(19) United States
(12) Patent Application Publication
(10) Pub. No.: US 2023/0186974 A1
(43) Pub. Date: Jun. 15, 2023

(54) MEMORY

(71) Applicant: CHANGXIN MEMORY TECHNOLOGIES, INC., Hefei (CN)

(72) Inventors: Hongwen LI, Hefei (CN); Weibing SHANG, Hefei (CN); Liang ZHANG, Hefei (CN)

(73) Assignee: CHANGXIN MEMORY TECHNOLOGIES, INC., Hefei (CN)

(21) Appl. No.: 17/806,073

(22) Filed: Jun. 8, 2022

(30) Foreign Application Priority Data
Dec. 15, 2021 (CN) 202111539943.8

(51) Int. Cl. G11C 11/4091; G11C 11/4096; G11C 11/4094; G11C 11/408; G11C 5/06

(52) U.S. Cl. CPC G11C 11/4091; G11C 11/4096; G11C 11/4094; G11C 11/4085; G11C 5/063

(57) ABSTRACT

A memory includes: bit lines extending along a first direction and word lines extending along a second direction; a column selection circuit and a plurality of memory modules that are arranged along the first direction; column-select lines extending along the first direction, wherein the column-select lines each are electrically connected to the column selection circuit, and the column selection circuit drives a corresponding amplification unit through one of the column-select lines; a read-write control driver circuit, wherein the read-write control driver circuit and the column selection circuit are located, respectively, on two adjacent sides of the plurality of memory modules as a whole; and a global data line extending along the second direction and an electrical connection line extending along a third direction, wherein the global data line is electrically connected to the read-write control driver circuit through the electrical connection line.

### CROSS-REFERENCE TO RELATED APPLICATION

This application claims priority to Chinese Patent Application No. 202111539943.8 filed on Dec. 15, 2021, the disclosure of which is hereby incorporated by reference in its entirety.

### BACKGROUND

A semiconductor memory is composed of many repeated memory cells, and each memory cell typically includes a capacitor and a transistor. In the transistor, a gate is connected to a word line (WL), a drain is connected to a bit line (BL), and a source is connected to the capacitor. A voltage signal on the WL can control the transistor to turn on or off, and then data information stored in the capacitor is read through the BL, or data information is written into the capacitor through the BL for storage.

Semiconductor memories can be classified into non-volatile memories and volatile memories. As a volatile memory, a dynamic random access memory (DRAM) has a high storage density, a fast read-write speed, and other advantages. The DRAM is widely used in various electronic systems. DRAMs can be classified into double data rate (DDR) DRAMs, graphics double data rate (GDDR) DRAMs, and low power double data rate (LPDDR) DRAMs.

### SUMMARY

Embodiments of the present disclosure relate to the technical field of semiconductors, and in particular, to a memory.

According to some embodiments of the present disclosure, an embodiment of the present disclosure provides a memory, including: bit lines (BLs) extending along a first direction and word lines (WLs) extending along a second direction; a column selection circuit and a plurality of memory modules that are arranged along the first direction, wherein each of the plurality of memory modules includes a memory array and an amplifier array that are arranged along the first direction, the memory array includes at least one memory cell, the amplifier array includes at least one amplification unit, each of the BLs is electrically connected to one terminal of a corresponding amplification unit, and each of the WLs is electrically connected to a corresponding memory cell; column-select lines (CSLs) extending along the first direction, wherein the CSLs each are electrically connected to the column selection circuit, and the column selection circuit drives a corresponding amplification unit through one of the CSLs; a read-write control driver circuit, wherein the read-write control driver circuit and the column selection circuit are located, respectively, on two adjacent sides of the plurality of memory modules as a whole; and a global data line extending along the first direction and an electrical connection line (CL) extending along a third direction, wherein the global data line is electrically connected to the read-write control driver circuit through the electrical CL, and the read-write control driver circuit is configured to drive a memory module corresponding to the global data line to write data into the memory cell through the global data line, or to read data from the memory cell and transmit the data to the global data line.

### BRIEF DESCRIPTION OF THE DRAWINGS

One or more embodiments are exemplified by corresponding drawings, and these exemplified descriptions do not constitute a limitation on the embodiments. Components with the same reference numerals in the drawings are denoted as similar components, and the drawings are not limited by scale unless otherwise specified.

FIG. 1 is a schematic structural diagram of a memory;

FIG. 2 is a schematic structural diagram of a memory according to some embodiments of the present disclosure;

FIG. 3 is a schematic structural diagram of a memory module of a memory according to some embodiments of the present disclosure;

FIG. 4 is a schematic diagram of a circuit structure of an amplification unit and a memory cell of a memory according to some embodiments of the present application;

FIG. 5 is a schematic layout diagram of data lines in a memory according to some embodiments of the present disclosure; and

FIG. 6 is a first schematic structural diagram of a memory according to some embodiments of the present disclosure.

FIG. 7 is a second schematic structural diagram of a memory according to some embodiments of the present disclosure.

FIG. 8 is a third schematic structural diagram of a memory according to some embodiments of the present disclosure.

FIG. 9 is a fourth schematic structural diagram of a memory according to some embodiments of the present disclosure.

FIG. 10 is a fifth schematic structural diagram of a memory according to some embodiments of the present disclosure.

FIG. 11 is a sixth schematic structural diagram of a memory according to some embodiments of the present disclosure.

### DETAILED DESCRIPTION

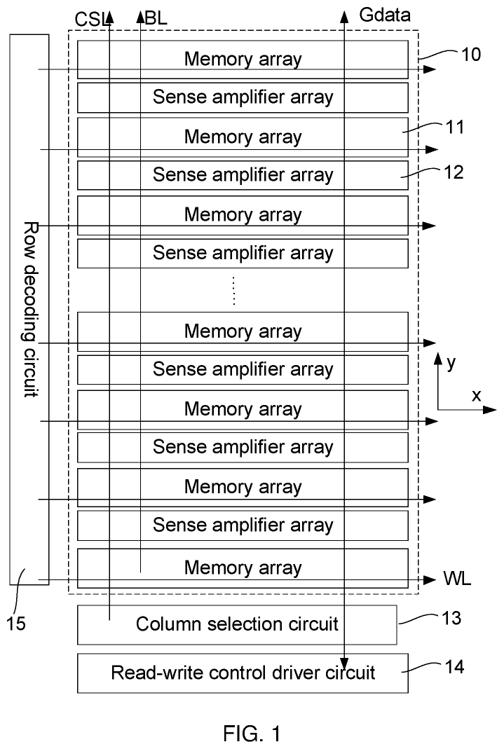

FIG. 1 is a schematic structural diagram of a memory. Referring to FIG. 1, the memory includes: a plurality of memory banks 10, wherein each of the plurality of memory banks 10 includes a plurality of memory modules, each of the plurality of memory modules (also referred to as sections) includes a memory array 11 and a sense amplifier array 12, the memory array 11 includes a plurality of memory cells arranged along an x direction, the sense amplifier array 12 includes a plurality of amplification units arranged along the x direction, a memory cell and an amplification unit that are located in a same column constitute a section, and it can be understood that a column is defined to be along a y direction and a row is defined to be along the x direction; a read-write control driver circuit 14, a column selection circuit (ydec) 13, and a row decoding circuit 15; a plurality of WLs extending along the x direction, wherein each of the plurality of WLs is connected to a memory array 11 of a corresponding row; a plurality of BLs extending along the y direction, wherein each of the plurality of BLs is connected to a memory array 11 of a corresponding column; CSLs extending along the y direction, wherein each of the CSLs is connected to an amplification unit of a sense amplifier array 12 of a corresponding column; and a global data line Gdata extending along the y direction, wherein the global data line is electrically connected to the amplification unit and the read-write control driver circuit 14, the read-write control driver circuit 14 is configured to drive a memory module corresponding to the global data line Gdata, and the row decoding circuit 15 is configured to provide a voltage to a WL to enable the WL.

In the above memory, the read-write control driver circuit 14 is located on one side of each of the plurality of memory banks 10, and the row decoding circuit 15 is located another side of each of the plurality of memory banks 10, which restricts a size and a shape of a chip to a certain extent and affects packaging of the chip or optimization of manufacturing efficiency. In addition, in the above memory, RC delays of driving different memory modules by the read-write control driver circuit 14 are quite different. Specifically, a memory module closest to the read-write control driver circuit 14 is defined as a first memory module, and a memory module furthest away from the read-write control driver circuit 14 is defined as a second memory module. A connection node between a global data line Gdata and the first memory module is far away from a connection node between the global data line Gdata and the second memory module. As a result, there is a large difference between time delays when the read-write control driver circuit drives the first memory module and the second memory module, and the read-write control driver circuit 14 needs to take a long time to drive the second memory module, causing an adverse impact on a read-write speed of the memory.

The embodiments of the present disclosure provide a memory in which a read-write control driver circuit and a column selection circuit are arranged, respectively, on two adjacent sides of a plurality of memory modules as a whole, to solve an RC delay problem, make a chip design more flexible, and improve storage performance of the memory.

In order to make the objectives, technical solutions and advantages of the embodiments of the present disclosure clearer, the embodiments of the present disclosure are described below with reference to the drawings. Those skilled in the art should understand that many technical details are proposed in the embodiments of the present disclosure to make the present disclosure better understood. However, even without these technical details and various changes and modifications made based on the following embodiments, the technical solutions claimed in the present disclosure may still be realized.

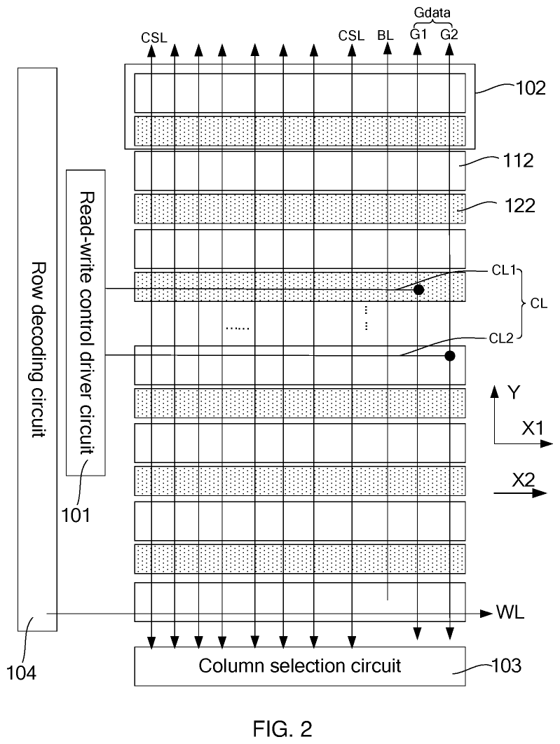

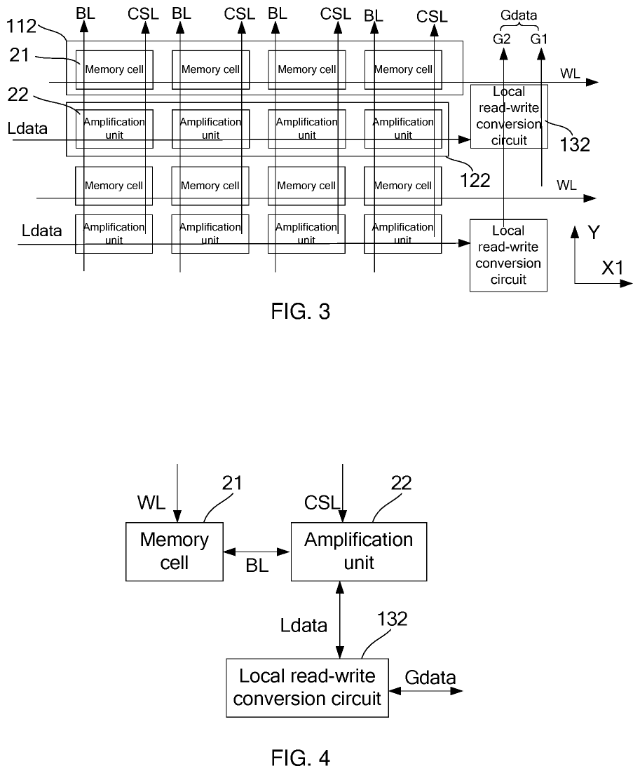

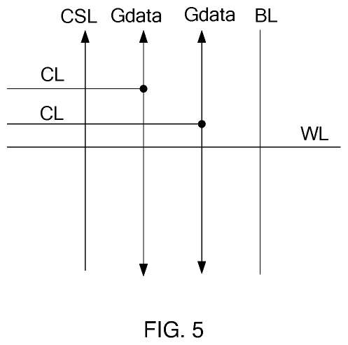

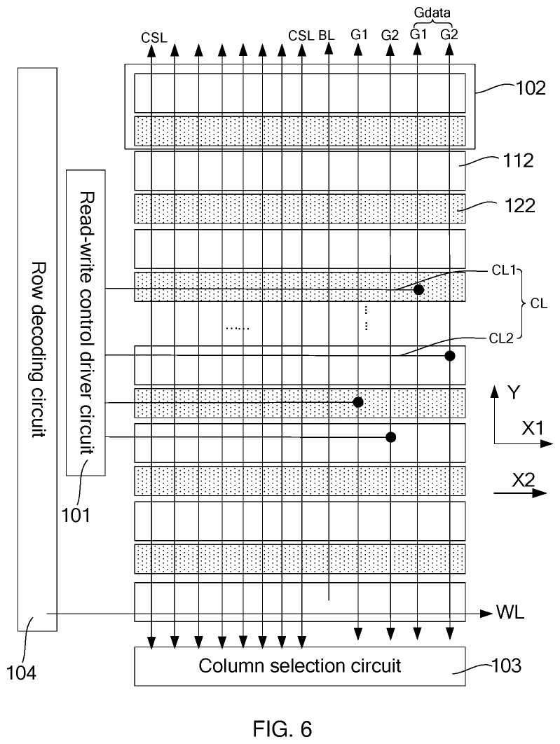

FIG. 2 is a schematic structural diagram of a memory according to some embodiments of the present disclosure, FIG. 3 is a schematic structural diagram of a memory module of a memory according to some embodiments of the present disclosure, FIG. 4 is a schematic diagram of a circuit structure of an amplification unit and a memory cell of a memory according to some embodiments of the present disclosure, FIG. 5 is a schematic layout diagram of data lines in a memory according to some embodiments of the present disclosure, and FIG. 6 to FIG. 11 are schematic structural diagrams of a memory according to some embodiments of the present disclosure. It can be understood that the memory cell described herein refers to an array unit formed by a plurality of basic memory cells that each are composed of a capacitor and a transistor.

Referring to FIG. 2 and FIG. 3, an embodiment of the present disclosure provides a memory, including: BLs extending along a first direction Y and WLs extending along a second direction X1; a column selection circuit 103 and a plurality of memory modules 102 that are arranged along the first direction Y, wherein each of the plurality of memory modules 102 includes a memory array 112 and an amplifier array 122 that are arranged along the first direction Y, the memory array 112 includes at least one memory cell 21, the amplifier array 122 includes at least one amplification unit 22, each of the BLs is electrically connected to one terminal of a corresponding amplification unit 22, and each of the WLs is electrically connected to a corresponding memory cell 21; a CSL extending along the first direction Y, wherein the CSL is electrically connected to the column selection circuit 103, and the column selection circuit 103 drives a corresponding amplification unit 22 through the CSL; a read-write control driver circuit 101, wherein the read-write control driver circuit 101 and the column selection circuit 103 are located, respectively, on two adjacent sides of the plurality of memory modules 102 as a whole; and a global data line Gdata extending along the first direction Y and an electrical CL (CL1) extending along a third direction X2, wherein the global data line Gdata is electrically connected to the read-write control driver circuit 101 through the electrical CL, and the read-write control driver circuit 103 is configured to drive a memory module 102 corresponding to the global data line to write data into the memory cell 21 through the global data line, or to read data from the memory cell 21 and transmit the data to the global data line.

It should be noted that only one BL and one WL are shown in FIG. 2. In fact, the memory includes a plurality of BLs and a plurality of WLs. In FIG. 3, only one BL and one CSL are shown in one memory cell. In fact, a plurality of BLs and a plurality of CSLs are connected in one memory cell.

In the above embodiment, the column selection circuit 103 and the read-write control driver circuit 101 are located, respectively, on the two adjacent sides of the plurality of memory modules 102 as a whole, such that a shape and a size of the memory can be adjusted more flexibly and manufacturing efficiency can be optimized. Moreover, an arrangement direction of the read-write control driver circuit 101 and an arrangement direction of the plurality of memory modules 102 are different from an extension direction of the global data line Gdata. In this way, signal transmission paths required by the read-write control driver circuit 101 to drive different memory modules 102 are only slightly different, so as to solve an RC delay problem and improve a read-write speed. In addition, in the above memory, different memory modules 102 can be driven by the read-write control driver circuit 101 through the electrical CL. This is conducive to reducing structural complexity of the read-write control driver circuit 101, a size of the read-write control driver circuit 101, and chip area of the memory.

In some embodiments, the memory may be a DRAM, for example, a double data rate (DRR) 4 DRAM or a DDR5 DRAM. In other embodiments, the memory may alternatively be a static random access memory (SRAM), a NAND memory, a NOR memory, a FeRAM, or a PcRAM.

Referring to FIG. 3, FIG. 3 is a detail of two adjacent memory modules 102 in FIG. 2. Each of the two adjacent memory modules 102 is referred to as a section. The memory array 112 may include a plurality of memory cells 21 arranged along the second direction X1, and the amplifier array 122 may include a plurality of amplification units 22 arranged along the second direction X1. In some embodiments, each of the plurality of amplification units 22 may be electrically connected to one memory cell 21 in a same memory module 102 to amplify data read from the memory cell 21 during a read operation. In other embodiments, each of the plurality of amplification units 22 may alternatively be electrically connected to one memory cell 21 in an adjacent memory module 102 to amplify data read from the memory cell 21 during a read operation. It can be understood that this embodiment of the present disclosure does not particularly limit an electrical connection correspondence between the memory cell and the amplification unit in the memory module, provided that the amplification unit can amplify the data read from the memory cell.

In some embodiments, the memory cell 21 may be a DRAM memory cell.

Referring to FIG. 4, FIG. 4 is a schematic diagram of functional modules of the amplification unit 22 and the memory cell 21. The amplification unit 22 is also referred to as a first sense amplifier (FSA). The amplification unit 22 has a control terminal, a first terminal, and a second terminal. The control terminal is electrically connected to the CSL to receive a column selection signal, the first terminal is electrically connected to the BL, and the second terminal is electrically connected to a local data line Ldata. The memory cell 21 is electrically connected to the WL and the BL. If the WL is enabled, the memory cell 21 electrically connected to the WL can perform a read operation, and data is transmitted between the corresponding memory cell 21 and the BL. Specifically, when the control terminal receives the column selection signal, the first terminal and the second terminal are turned on to transmit the data between the BL and the local data line Ldata.

The BLs are electrically connected to memory cells 21 arranged along the first direction Y in a plurality of memory arrays 112, and a same BL is electrically connected to all the memory cells 21 arranged along the first direction Y. It can be understood that the BL can be presented as a bus, and the same BL is a same BL bus.

The WLs are electrically connected to memory cells 21 arranged along the second direction X1 in the plurality of memory arrays 112, and a same WL is electrically connected to a row of memory cells 21 arranged along the second direction X1 in a same memory array 112. It can be understood that the WL can be presented as a bus, and the same WL is a same WL bus.

The column selection circuit 103, commonly referred to as a YDEC circuit, is configured to provide the column selection signal for the amplification unit 22 to select the amplification unit 22 to transmit the data between the BL and the local data line Ldata. The CSL is electrically connected to the column selection circuit 103 through the electrical CL, and is configured to provide the column selection signal for a control terminal of a corresponding amplification unit 22 to select the amplification unit 22, such that the amplification unit 22 realizes data transmission and amplification.

The electrical CL is configured to electrically connect the read-write control driver circuit 101 and the global data line Gdata, such that the read-write control driver circuit 101 is electrically connected to a corresponding memory module 102. In some embodiments, the third direction X2 may be the same as the second direction X1, in other words, an extension direction of the electrical CL may be the same as that of the WL, and the first direction Y may be perpendicular to the third direction X2. In this way, a length of the electrical CL can be as short as possible, such that a path required by the read-write control driver circuit 101 to drive the memory module 102 can be as short as possible, which is conducive to further improving read-write performance of the memory.

Each memory module 102 arranged along the first direction Y may be defined as a section. In some embodiments, the read-write control driver circuit 101 may be arranged in the middle of one side of the plurality of memory modules 102 as a whole, which is conducive to further reducing a difference between signal transmission time required by the read-write control driver circuit 101 to drive head-end and tail-end sections, so as to further improve overall performance of the memory. The CSL is configured to turn on a plurality of BLs in a same section and a corresponding local data line Ldata. Each section includes a plurality of CSLs, and may further include a conventional CSL and a redundant CSL. When the memory operates, one CSL in each section is selected and turned on.

As previously analyzed, in some embodiments, the memory may further include local data lines Ldata. Each of the local data lines Ldata extends along the second direction X1, and a same local data line Ldata is electrically connected to second terminals of amplification units 22 in a same amplifier array 122. It can be understood that one amplifier array 122 may be connected to a plurality of local data lines Ldata.

In some embodiments, the memory may further include a complementary BL. Accordingly, the memory may further include a local complementary data line.

In some embodiments, referring to FIG. 3 and FIG. 4, the memory module 102 may further include a local read-write conversion circuit 132, and the local read-write conversion circuit 132 is electrically connected to the second terminal of the amplification unit 22. Specifically, the local read-write conversion circuit 132 is electrically connected to the second terminal of the amplification unit 22 through the local data line. The local read-write conversion circuit 132 is configured to implement data transmission between the local data line and the global data line Gdata. More specifically, a same global data line Gdata can be electrically connected to a plurality of local read-write conversion circuits 132. That the read-write control driver circuit 101 drives the memory module 102 means that, in a writing stage, the read-write control driver circuit 101 drives the local read-write conversion circuit 132 corresponding to the memory module 102 to perform data transmission from the local data line to the global data line Gdata, and in a reading stage, the read-write control driver circuit 101 drives the local read-write conversion circuit 132 corresponding to the memory module 102 to perform data transmission from the global data line Gdata to the local data line.

Referring to FIG. 3, the local read-write conversion circuit 132 may be arranged on one side of the amplifier array 122, and the local read-write conversion circuit 132 of each of the plurality of memory modules 102 is arranged on a same side of a corresponding amplifier array 122. In this way, a length of the global data line Gdata can be reduced and the read-write speed can be improved. In other embodiments, the local read-write conversion circuit 132 may be arranged inside the amplifier array 122, in other words, between any adjacent amplification units 22, and local read-write conversion circuits 132 of different memory modules 102 are arranged in a same position of corresponding amplifier arrays 122. For example, the local read-write conversion circuit 132 of each of the plurality of memory modules 102 is arranged between a fifth amplification unit 22 and a sixth amplification unit 22, or the local read-write conversion circuit 132 of each of the plurality of memory modules 102 is arranged between a tenth amplification unit 22 and an eleventh amplification unit 22.

Referring to FIG. 5, FIG. 5 is a schematic layout diagram of data lines in the memory according to this embodiment of the present disclosure. The data lines include the global data line Gdata, the electrical CL, the CSL, the BL and the WL. Directions of the BL, the global data line Gdata, and the CSL are the same, and directions of the electrical CL and the WL are the same.

In some embodiments, referring to FIG. 2, the memory may further include a row decoding circuit 104. The row decoding circuit 104 is configured to select, based on the WL, the memory cell 21 electrically connected to the WL, such that the memory cell 21 electrically connected to the WL performs read and write operations. Specifically, the row decoding circuit 104 and the read-write control driver circuit 101 may be located on a same side of the plurality of memory modules 102, and the row decoding circuit 104 may be located on one side of the read-write control driver circuit 101 far away from the plurality of memory modules 102.

In some embodiments, the row decoding circuit 104 and the read-write control driver circuit 101 may be located at a same layer of the memory. In other embodiments, the row decoding circuit 104 and the read-write control driver circuit 101 may be located at different layers of the memory.

In the first direction Y, the plurality of memory modules 102 are sorted by natural number in ascending order, a memory module 102 in an odd position is defined as a first memory module, and a memory module 102 in an even position is defined as a second memory module; the global data line Gdata includes: a first global data line G1 corresponding to the first memory module, and a second global data line G2 corresponding to the second memory module; and the electrical CL includes: a first electrical CL (CL1) electrically connected to the first global data line G1 and the read-write control driver circuit 101, and a second electrical CL (CL2) electrically connected to the second global data line G2 and the read-write control driver circuit 101. The first global data line G1 and the second global data line G2 are independent of each other, and the first electrical CL (CL1) and the second electrical CL (CL2) are independent of each other. Both the first electrical CL (CL1) and the second electrical CL (CL2) extend along the third direction X2.

Specifically, in some embodiments, referring to FIG. 2, each first global data line G1 may correspond to all first memory modules, and each second global data line G2 may correspond to all second memory modules. That is, the read-write control driver circuit 101 can drive all the first memory modules at the same time through the first global data line G1, and the read-write control driver circuit 101 can drive all the second memory modules at the same time through the second global data line G2. This is conducive to reducing a quantity of first global data lines G1, a quantity of second global data lines G2, and power consumption of the memory.

In other embodiments, referring to FIG. 6, there may be a plurality of first global data lines G1 and a plurality of second global data lines G2, each of the plurality of first global data line G1 corresponds to some first memory modules, and each of the plurality of second global data lines G2 corresponds to some second memory modules. That is, the read-write control driver circuit 101 only needs to drive some first memory modules or some second memory modules each time, which is conducive to reducing load that needs to be driven by the read-write control driver circuit 101 each time and improving a signal transmission speed. For example, one first global data line G1 is connected to 1^{st}, 5^{th}, 9^{th}, and 13^{th} memory modules 102, and one second global data line G2 is connected to 2^{nd}, 6^{th}, 10^{th}, and 14^{th} memory modules 102; and another first global data line G1 is connected to 3^{rd}, 7^{th} and 11^{th} memory modules 102, and another second global data line G2 is connected to 4^{th}, 8^{th}, and 12^{th} memory modules 102.

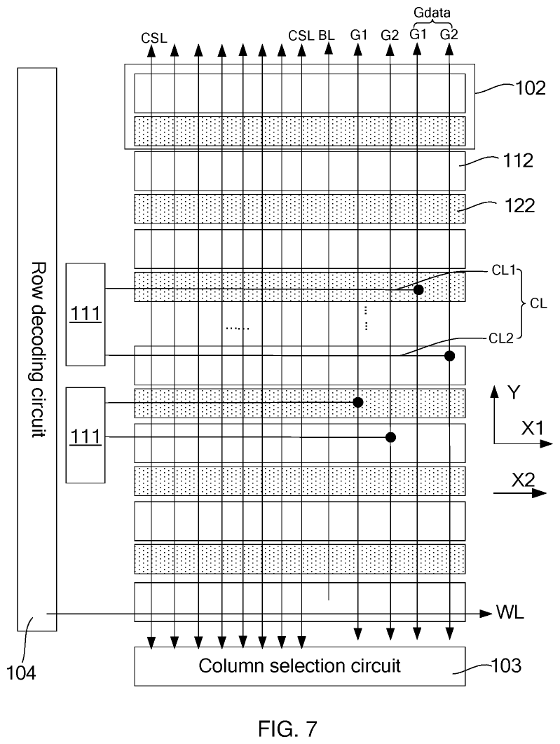

In some embodiments, referring to FIG. 7, FIG. 7 is a different schematic structural diagram of the memory according to this embodiment of the present disclosure. The read-write control driver circuit (not shown in the figure) may include a plurality of read-write control driving units 111 arranged along the first direction Y, wherein each of the plurality of read-write control driving units 111 is electrically connected to at least one of the plurality of first global data lines G1 and at least one of the plurality of second global data lines G2 through the electrical CL. In this way, different sections can be driven by different read-write control driving units 111, thereby realizing more flexible driving manners for different sections in the memory.

In some embodiments, global data lines Gdata electrically connected to different read-write control driving units 111 are distributed at intervals. For example, some global data lines Gdata are distributed at edges of the plurality of memory modules 102, and other global data lines Gdata are distributed in middle regions of the plurality of memory modules 102. Different global data lines Gdata are distributed at intervals, which can avoid signal interference between different global data lines Gdata and is conducive to further improving storage performance of the memory.

It can be understood that in some embodiments, there may be a plurality of global data lines Gdata, and all the global data lines Gdata may be distributed at the edges of the plurality of memory modules 102.

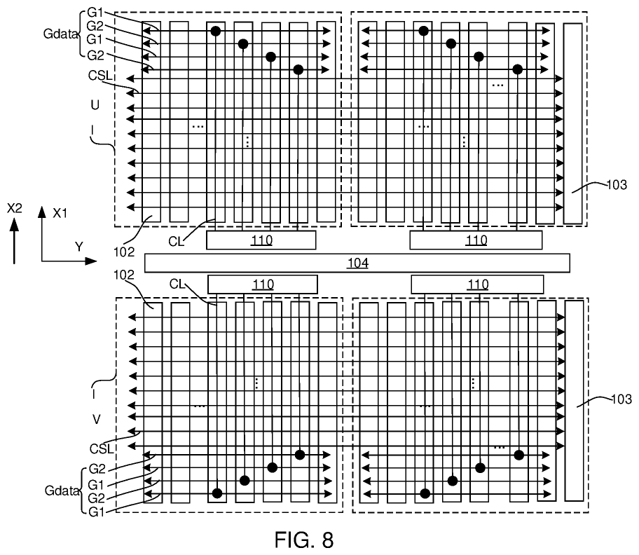

In some embodiments, with reference to FIG. 3 and FIG. 8 to FIG. 11, wherein FIG. 8 to FIG. 11 are different schematic structural diagrams of the memory according to some embodiments of the present disclosure, the plurality of memory modules 102 may be divided into at least two module regions I arranged along the first direction Y, and each of the at least two module regions I includes a plurality of memory modules 102; and the read-write control driver circuit 101 may include at least two read-write control driving modules 110 arranged along the first direction Y, wherein each of the at least two read-write control driving modules 110 is located on one side of a corresponding module region I, and is electrically connected to a corresponding global data line Gdata through the electrical CL. It should be noted that FIG. 8 to FIG. 11 do not show the amplifier array, the memory cell, the amplification unit, the WL, or the BL, and only show the memory array in a form of a box, and an amplifier array between adjacent memory arrays is not shown. For arrangement of the amplifier array, the memory cell, the amplification unit, the WL, and the BL, reference may be made to the corresponding description in FIG. 2 to FIG. 7.

Specifically, each of the at least two module regions I contains a same quantity of memory modules 102. In addition, the memory may further be divided into a high-bit address memory bank U and a low-bit address memory bank V. The high-bit address memory bank U and the low-bit address memory bank V each include a plurality of memory modules 102.

Memory cells 21 in different module regions I are connected to different WLs, in other words, a WL in a module region I is enabled while WLs in other module regions I are not enabled. In this case, because different module regions I have mutually independent global data lines Gdata, the read-write control driving module 110 may select only a global data line Gdata corresponding to a module region I corresponding to the enabled WL to drive a memory module 102 in the module region I, while other module regions I do not need to be driven by the read-write control driving module 110, which can reduce more power consumption. Moreover, a scheme in which each of the at least two module regions I has a mutually independent global data line Gdata can reduce a length of each global data line Gdata, which is conducive to reducing resistance of the global data line Gdata. Moreover, load on each global data line Gdata is reduced, which is conducive to reducing a heat loss and power consumption. It can be understood that the load includes the memory module 102 electrically connected to the global data line Gdata.

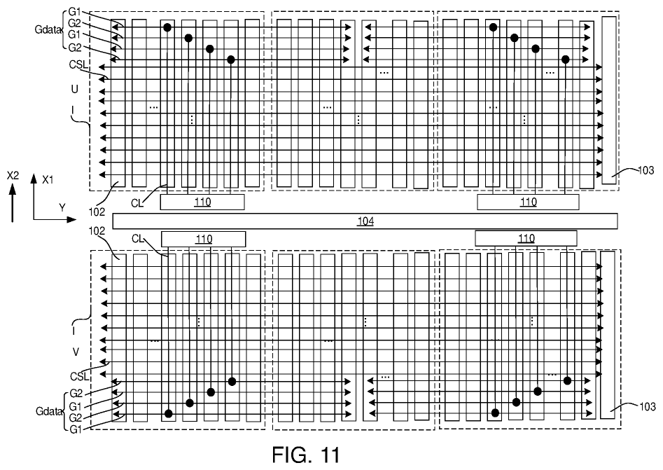

As shown in FIG. 8, in some embodiments, there may be two module regions I. As shown in FIG. 11, in other embodiments, there may alternatively be three module regions I. It can be understood that a quantity of module regions I may be reasonably set based on an actual situation, and the quantity of module regions I is not limited in this embodiment of the present disclosure.

In some embodiments, the read-write control driver circuit 101 is configured to: when a WL corresponding to the module region I is enabled, the read-write control driving module 110 corresponding to the module region I drives the memory module 102 in the module region I through the global data line Gdata. As can be seen above, this is conducive to reducing the power consumption of the memory.

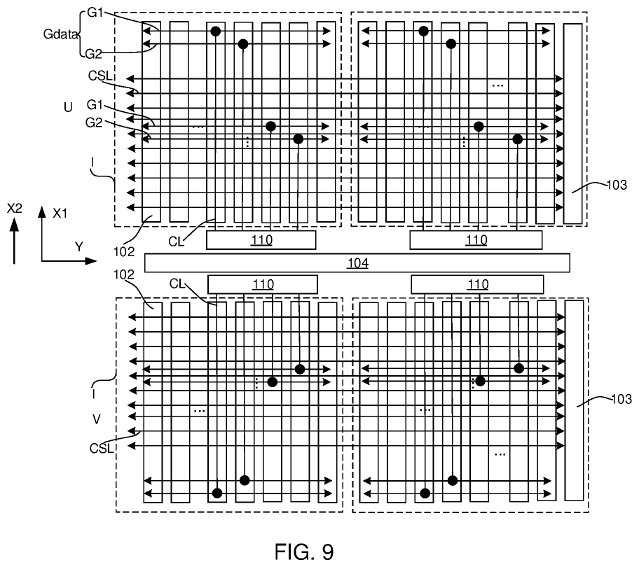

Referring to FIG. 8 and FIG. 9, in some embodiments, there are a plurality of global data lines Gdata in a same module region I, the plurality of global data lines Gdata are divided into at least two groups of global data lines Gdata, and each of the at least two groups of global data lines Gdata corresponds to at least two adjacent memory modules 102. The memory modules 102 corresponding to the two groups of global data lines Gdata can be driven by the read-write control driver circuit 101 separately, realizing more flexible driving manners for different memory modules 102. In addition, each group of global data lines Gdata corresponds to at least two adjacent memory modules 102 to ensure that the adjacent memory modules 102 can be driven at the same time.

Specifically, in some embodiments, referring to FIG. 8, for the same module region I, all global data lines Gdata may be arranged next to each other. In this way, there is no need to consider layout interference between the global data line Gdata and the CSL.

In other embodiments, referring to FIG. 9, for the same module region I, different groups of global data lines Gdata may be distributed at intervals. Different groups of global data lines Gdata are spaced from each other, which can avoid signal interference between the different groups of global data lines Gdata.

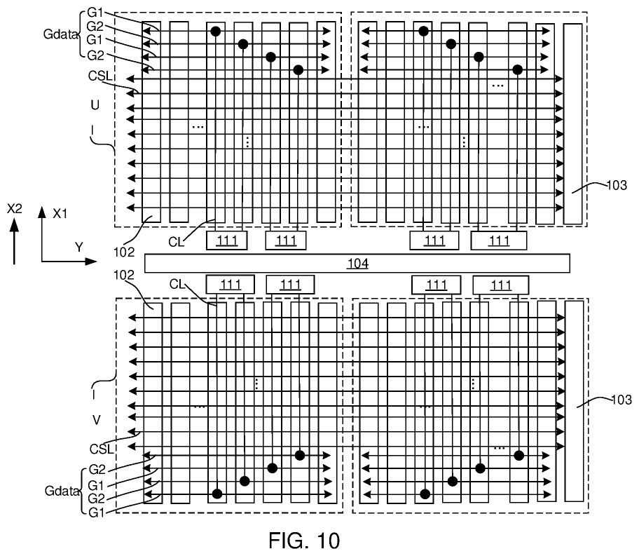

Referring to FIG. 10, in some embodiments, for a same module region I, the read-write control driving module (not shown in the figure) may include a plurality of read-write control driving units 111 arranged along the first direction Y, and each of the plurality of read-write control driving units 111 is electrically connected to at least one group of global data lines Gdata. In this way, different memory modules 102 in a same module region I can be independently driven by different read-write control driving units 111. In addition, global data lines Gdata connected to different read-write control driving units 111 may be distributed at intervals, which can avoid signal interference between different groups of global data lines Gdata, and further improve the storage performance of the memory. It should be noted that only two module regions I are shown in FIG. 10. The quantity of module regions I is not limited in this embodiment of the present disclosure. There may be three, four, or more module regions I.

It should be noted that in some embodiments, global data lines Gdata of different module regions I can be independent of each other. In some embodiments, as shown in FIG. 11, the global data line Gdata may correspond to the at least two module regions, and at least some memory modules 102 in at least two module regions I connected to a same global data line Gdata share the global data line Gdata. In this way, the global data line Gdata can be shared by adjacent module regions I, which is conducive to reducing a quantity of global data lines Gdata, and the read-write control driving module 110 can be shared by the adjacent module regions I.

An embodiment of the present disclosure provides a memory with a superior structure and superior performance. A column selection circuit 103 and a read-write control driver circuit 101 are arranged on different sides of a plurality of memory modules 102 as a whole, which makes a chip design of the memory more flexible, helps to reduce chip area, and reduces time required for transmitting a column selection signal to an amplification unit 22 far away from the read-write control driver circuit 101. This is conducive to solving a RC delay problem and improving read-write performance of the memory.

The technical solutions provided in the embodiments of the present disclosure have the following advantages:

The embodiments of the present disclosure provide a memory with a superior structure and superior performance. A column selection circuit and a plurality of memory modules are arranged along a first direction. A read-write control driver circuit and the column selection circuit are located, respectively, on two adjacent sides of the plurality of memory modules as a whole. A global data line extends along a second direction, and an electrical CL extends along a third direction. The global data line is electrically connected to the read-write control driver circuit through the electrical CL, and the read-write control driver circuit is configured to drive a memory module corresponding to the global data line. The read-write control driver circuit and the column selection circuit are located, respectively, on the two adjacent sides of the plurality of memory modules as a whole, which makes a chip layout corresponding to the memory more flexible. In addition, the global data line and the electrical CL forms a T-shape structure. In this way, a difference between signal transmission paths required by the read-write control driver circuit to drive head-end and tail-end memory modules is small, which solves an RC delay problem of the read-write control driver circuit and is conducive to improving a read-write speed of the memory.

Those skilled in the art can understand that the above implementations are specific embodiments for implementing the present disclosure. In practical applications, various changes may be made to the above embodiments in terms of form and details without departing from the spirit and scope of the present disclosure. Any person skilled in the art may make changes and modifications to the embodiments without departing from the spirit and scope of the present disclosure. Therefore, the protection scope of the present disclosure should be subject to the scope defined by the claims.

What is claimed is:

1. A memory, comprising:
bit lines extending along a first direction and word lines extending along a second direction;
a column selection circuit and a plurality of memory modules that are arranged along the first direction, wherein each of the plurality of memory modules comprises a memory array and an amplifier array that are arranged along the first direction, the memory array comprises at least one memory cell, the amplifier array comprises at least one amplification unit, each of the bit lines is electrically connected to one terminal of a corresponding amplification unit, and each of the word lines is electrically connected to a corresponding memory cell;
column-select lines extending along the first direction, wherein the column-select lines each are electrically connected to the column selection circuit, and the column selection circuit drives a corresponding amplification unit through one of the column-select lines;
a read-write control driver circuit, wherein the read-write control driver circuit and the column selection circuit are located, respectively, on two adjacent sides of the plurality of memory modules as a whole; and
a global data line extending along the first direction and an electrical connection line extending along a third direction, wherein the global data line is electrically connected to the read-write control driver circuit through the electrical connection line, and the read-write control driver circuit is configured to drive a memory module corresponding to the global data line to write data into the memory cell through the global data line, or to read data from the memory cell and transmit the data to the global data line.

2. The memory according to claim 1, wherein in the first direction, the plurality of memory modules are sorted by natural number in ascending order, a memory module in an odd position is defined as a first memory module, and a memory module in an even position is defined as a second memory module;
the global data line comprises: a first global data line corresponding to the first memory module, and a second global data line corresponding to the second memory module; and
the electrical connection line comprises: a first electrical connection line electrically connected to the first global data line and the read-write control driver circuit; and a second electrical connection line electrically connected to the second global data line and the read-write control driver circuit.

3. The memory according to claim 2, wherein each first global data line corresponds to all first memory modules, and each second global data line corresponds to all second memory modules.

4. The memory according to claim 2, wherein there are a plurality of first global data lines and a plurality of second global data lines, wherein each of the plurality of first global data lines corresponds to some first memory modules, and each of the plurality of second global data lines corresponds to some second memory modules.

5. The memory according to claim 4, wherein the read-write control driver circuit comprises:
a plurality of read-write control driving units arranged along the first direction, wherein each of the plurality of read-write control driving units is electrically connected to at least one of the plurality of first global data lines and at least one of the plurality of second global data lines.

6. The memory according to claim 4, wherein global data lines electrically connected to different read-write control driving units are distributed at intervals.

7. The memory according to claim 1, wherein there are a plurality of global data lines, and all the global data lines are distributed at edges of the plurality of memory modules.

8. The memory according to claim 1, wherein the plurality of memory modules are divided into at least two module regions arranged along the first direction, each of the at least two module regions comprises at least two of the plurality of memory modules, and different module regions have mutually independent global data lines; and
the read-write control driver circuit comprises:
at least two read-write control driving modules arranged along the first direction, wherein each of the at least two read-write control driving modules is located on one side of a corresponding module region, and is electrically connected to a corresponding global data line through the electrical connection line.

9. The memory according to claim 8, wherein the read-write control driver circuit is configured to: when a word line corresponding to the module region is enabled, the read-write control driving module corresponding to the module region drives the memory module in the module region through the global data line.

10. The memory according to claim 8, wherein there are a plurality of global data lines in a same module region, the plurality of global data lines are divided into at least two groups of global data lines, and each of the at least two groups of global data lines corresponds to at least two adjacent memory modules.

11. The memory according to claim 10, wherein for the same module region, all the global data lines are arranged next to each other, or different groups of global data lines are distributed at intervals.

12. The memory according to claim 10, wherein for the same module region, the read-write control driving module comprises a plurality of read-write control driving units arranged along the first direction, and each of the plurality of read-write control driving units is electrically connected to at least one group of global data lines.

13. The memory according to claim 8, wherein each of the at least two module regions contains a same quantity of memory modules.

14. The memory according to claim 1, wherein the third direction is the same as the second direction.

15. The memory according to claim 1, wherein the first direction is perpendicular to the second direction.

16. The memory according to claim 1, further comprising a row decoding circuit, wherein the row decoding circuit is configured to select, based on the word line, the memory cell electrically connected to the word line; and the row decoding circuit is located on one side of the read-write control driver circuit far away from the plurality of memory modules.
